(19) United States
(12) Patent Application Publication
(10) Pub. No.: US 2024/0379285 A1
(43) Pub. Date: Nov. 14, 2024

(54) NOVEL HIGH EFFICIENCY CENTER TAPPED TRANSFORMER STRUCTURE

(71) Applicant: Flex Ltd., Singapore (SG)

(72) Inventors: Hua Min XU, Nanshan (CN); Qian ZHANG, Nanshan (CN); Yi ZHANG, Nanshan (CN); Shun Long TANG, Nanshan (CN); Zhen Mei WAN, Nanshan (CN)

(73) Assignee: Flex Ltd., Singapore (SG)

(21) Appl. No.: 18/332,949

(22) Filed: Jun. 12, 2023

(30) Foreign Application Priority Data
May 9, 2023 (CN) 202310524889.2

(51) Int. Cl. H01F 27/34; H01F 27/28; H01F 27/30; H01F 29/02; H01F 41/02

(52) U.S. Cl. CPC H01F 27/346; H01F 27/2823; H01F 27/306; H01F 29/025; H01F 41/02; H01F 2027/348

(57) ABSTRACT

Devices and methods for coupling an interleaved aligned first and second secondary windings coil structure with a primary winding of a center tapped transformer are provided. In particular, a method for forming a center tapped transformer includes forming a winding core, winding a primary winding around the winding core and winding a first secondary winding and a second secondary winding in an interleaved alignment around the primary winding.

### CROSS REFERENCE TO RELATED APPLICATION

The present application claims the benefit of and priority to Chinese Patent Application No. 202310524889.2 filed May 9, 2023, the entire disclosure of which is hereby incorporated by reference for all that it teaches and for all purposes.

### FIELD

The present disclosure is generally directed to transformers, in particular, the present disclosure is directed to a high efficiency center tapped transformer with reduced coil loss and enhanced coupling between the primary winding and each of the secondary windings.

### BACKGROUND

A transformer is a passive electrical component that transfers electrical energy from one electrical circuit to another circuit or multiple circuits. Based on its construction, the transformer is broadly classified into the core type transformer and the shell type transformer. In the core type transformer, the magnetic circuit of the transformer consists of two vertical sections called limbs and two horizontal sections called yokes where half of each of the primary winding and the secondary winding is place on each limb of the magnetic core so that leakage flux can be minimized. In the shell type transformer, however, one center limb, two outer limbs and two yokes are provided where both the primary and secondary windings are placed on the center limb. The function of the two outer limbs is to complete the path of low reluctance for magnetic flux. In the shell type transformer, the primary and secondary windings are divided into subsections, where the low voltage winding and the high voltage winding subsections are alternatively placed on the center limb in the form of a sandwich.

The working of a center tapped transformer is very similar to the working of a standard transformer with both transformers transferring primary voltage or energy from the primary winding to the secondary winding through inductive coupling. The alternating current (AC) in the primary winding induces a varying magnetic flux in the transformer core. The only difference between the center tapped transformer and the standard transformer is that there is a tap at the midpoint or center of the secondary winding that divides the center tapped transformer into two parts. These two parts allow the center tapped transformer to provide two separate output voltages which are equal in magnitude, but opposite in polarity to each other.

Referring back to the shell type transformer, there are many shortcomings with respect to a center trapped shell type transformer. Because only half of the primary winding is covered by a working secondary winding, the other half of the primary winding is covered by a non-working secondary winding. This inefficient coupling between the primary winding and the secondary windings causes large eddy current loss in the coil of the primary winding. In addition, the current balance is poor in the two secondary windings of the center tapped transformer which uses a parallel structure in the secondary windings. For example, in large current circuits, flat copper wires in a parallel structure are usually used to decrease the AC resistance loss. In the parallel structure, the current theoretically flows through each flat copper wire at the same or an average rate. For actual purposes, however, the current flows in each flat copper wire at a different rate. Furthermore, this poor current balance issue with the two secondary windings will cause more loss on the secondary windings and the primary winding.

The use of a single thick copper sheet or wire or the use of many thin copper sheets or wires in parallel only reduces the direct current (DC) resistance of the secondary windings, but provides very limited reduction in the AC resistance, so the AC loss of the copper sheet(s) or wire(s) is still very large. Therefore, there is a need for a center tapped transformer with reduced coil loss for improved efficiency.

### BRIEF SUMMARY

A method for forming a center tapped transformer includes forming a winding core, winding a primary winding around the winding core and winding a first secondary winding and a second secondary winding in an interleaved alignment around the primary winding.

Any of the aspects herein, further including alternating members of the first secondary winding with corresponding members of the second secondary winding to form an interleaved aligned first and second secondary windings coil structure.

Any of the aspects herein, further including connecting center terminals for each member of the interleaved aligned first and second secondary windings coil structure to a busbar and coupling the busbar to a printed circuit board.

Any of the aspects herein, further including coupling connection legs for each member of the interleaved aligned first and second secondary windings coil structure to the printed circuit board.

Any of the aspects herein, further including forming each of the first secondary winding and the second secondary winding from Litz wire.

Any of the aspects herein, wherein each of the first and second secondary windings includes one turn.

Any of the aspects herein, further including combining core members together to form the winding core.

Any of the aspects herein, wherein each of the core members includes an E-shaped section.

Any of the aspects herein, further including applying the center tapped transformer in a full wave rectifier circuit.

Any of the aspects herein, further including forming the primary winding from Litz wire.

A center tapped transformer includes a winding core, a primary winding wound around the winding core and a first secondary winding and a second secondary winding wound in an interleaved alignment around the primary winding.

Any of the aspects herein, wherein members of the first secondary winding are alternated with corresponding members of the second secondary winding to form an interleaved aligned first and second secondary windings coil structure.

Any of the aspect herein, further including a busbar, wherein center terminals for each member of the interleaved aligned first and second secondary windings coil structure is connected to the busbar, and wherein the busbar is coupled to a printed circuit board.

Any of the aspects herein, wherein connection legs for each member of the interleaved aligned first and second secondary windings coil structure is coupled to the printed circuit board.

Any of the aspect herein, wherein each of the first secondary winding and the second secondary winding is formed from Litz wire.

Any of the aspects herein, wherein each of the first and second secondary windings includes one turn.

Any of the aspects herein, wherein core members are combined together to form the winding core.

Any of the aspects herein, wherein each of the core members includes an E-shaped section.

Any of the aspect herein, wherein the center tapped transformer is applied in a full wave rectifier circuit.

A circuit module includes a circuit board having at least one mounting area and a center tapped transformer coupled to the at least one mounting area. The center tapped transformer includes a winding core, a primary winding wound around the winding core and a first secondary winding and a second secondary winding wound in an interleaved alignment around the primary winding.

### BRIEF DESCRIPTION OF THE DRAWINGS

FIG. 1 depicts a schematic representation of a full wave rectifier with a center tapped transformer circuit in accordance with embodiments of the present disclosure;

FIG. 2 depicts a perspective exploded view of a conventional center tapped transformer;

FIG. 3 depicts a perspective view of a conventional coil structure illustrated in FIG. 2;

FIG. 4 depicts a first perspective exploded view of a center tapped transformer according to embodiments of the present disclosure;

FIG. 5 depicts a perspective view of an unassembled coil structure of the secondary windings illustrated in FIG. 4 according to embodiments of the present disclosure;

FIG. 6 depicts a perspective view of an assembled coil structure of the secondary windings illustrated in FIG. 4 according to embodiments of the present disclosure;

FIG. 7 depicts a second perspective exploded view of a center tapped transformer according to embodiments of the present disclosure;

FIG. 8 illustrates a method for forming a center tapped transformer with reduced coil loss and enhanced coupling between the primary winding and each of the secondary windings according to embodiments of the present disclosure.

### DETAILED DESCRIPTION

It is with respect to the above issues and other problems that the embodiments presented herein were contemplated. In general, embodiments of the present disclosure provide devices and methods for coupling an interleaved aligned first and second secondary windings coil structure with a primary winding of a center tapped transformer are provided. In particular, a method for forming a center tapped transformer includes forming a winding core, winding a primary winding around the winding core and winding a first secondary winding and a second secondary winding in an interleaved alignment around the primary winding.

As used herein, a “Litz wire” refers to a wire that includes a plurality of individual strands of conductive material that are braided, stranded, or woven together into a bundled cable-like structure that is covered with an outer jacket. Each of the individual strands in the Litz wire is constructed of an electrically conductive material. In addition, each of the individual strands is electrically insulated from the other individual strands by an electrical insulator (i.e., each strand is coated with an electrical insulator material) that is separate from the outer jacket. The braided, stranded, or woven features of the individual strands may be in a weaving or twisting pattern such that the individual strands are located on an exterior of the bundle for a length of the Litz wire (where the electromagnetic field changes are weakest and the strands exhibit low resistance), and are located on an interior of the bundle for a length of the Litz wire (where the electromagnetic field changes are the strongest and the strands exhibit low resistance). In addition, if each strand has a comparable impedance, a current applied to the Litz wire is distributed equally among every strand within the Litz wire that contacts the source of the current. This allows the interior of the Litz wire to contribute to the overall conductivity of the bundle. That is, the magnetic fields generated by current flowing through the individual strands of the Litz wire are in directions such that they have a reduced tendency to generate an opposing electromagnetic field in the other strands. As such, for the Litz wire as a whole, the skin effect (the tendency of an alternating electric current to become distributed within a conductor such that the current density is largest near the surface of the conductor and decreases with greater depths in the conductor) and associated power losses when used in high-frequency applications are reduced. The ratio of distributed inductance to distributed resistance is increased, relative to a solid conductor, resulting in a higher Q factor at these frequencies. In addition, the close proximity of the individual strands to one another, when separated into discrete windings, results in increased coupling and/or decreased conduction loss relative to other transformers utilizing other windings, as described herein. Various other characteristics of a Litz wire should generally be understood.

A “skin effect” is a tendency of a current to become distributed within an electrical current conductor such that the current density is largest near the surface of the conductor and decreases with greater depths in the conductor. That is, the electric current flows primarily at the “skin” of the electrical current conductor between the outer surface and a particular level called the skin depth. The skin effect causes an effective resistance of the electrical current conductor to increase at higher frequencies where the skin depth is smaller, thus reducing the effective cross-section of the electrical current conductor. The skin effect is due to opposing eddy currents induced by the changing magnetic field resulting from the current. At 100k Hertz (Hz) in copper, the skin depth is about 0.24 mm. At higher frequencies, the skin depth becomes smaller. Increased current resistance due to the skin effect can be mitigated using Litz wire.

A “proximity effect” is the result of current flowing through one or more nearby conductors, such as within a closely wound coil of wire, which causes the distribution of current within the first conductor to be constrained to smaller regions. This crowding of the current provides an increase in effective resistance of the circuit, which increases with the frequency of the current flowing through the circuit.

“Leakage inductance” is the result of an imperfectly coupled transformer. That is, leakage inductance is affected by design factors in a transformer. For example, the physical distance between windings may directly contribute to leakage inductance. The further the physical distance between windings, the greater the leakage inductance. This is because each winding behaves as a self-inductance constant in series with the respective ohmic resistance constant of the winding, which interacts with the mutual inductance constant of the transformer. The winding self-inductance constant and associate leakage inductance is due to leakage flux not linking with all turns of each imperfectly coupled winding. The leakage flux alternately stores and discharges magnetic energy with each electrical cycle acting as an inductor in series with each of the primary and secondary circuits.

In certain two-winding transformers, leakage inductances exist in each winding because the magnetic flux is not perfectly coupled between the two windings. It may be desirable to minimize these leakage inductances because the leakage inductances generate unexpected ringing/resonance in voltage and current waveforms in the circuit, which may also be referred to as noise or EMI. The leakage inductances may also deteriorate the voltage gain of the transformer, which may lead to a loss of power and/or signal transferred through the transformer.

Certain transformers may utilize interleaved foil windings (e.g., sandwich winding) to achieve an increased coupling. However, while such transformers may potentially reduce leakage inductance, the flat shape of the conductor may suffer from high AC resistance.

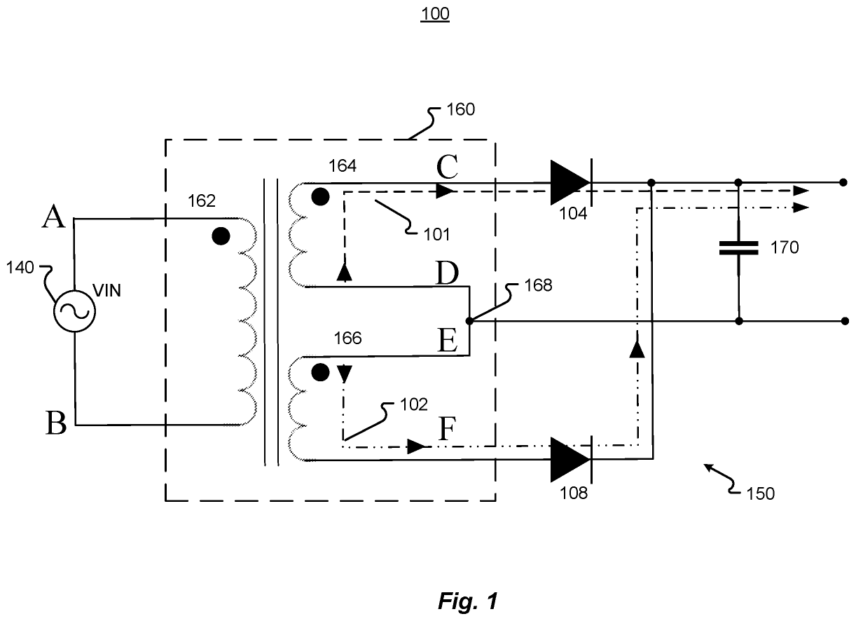

FIG. 1 depicts a schematic representation 100 of a full wave rectifier with a center tapped transformer 160 circuit 150 in accordance with embodiments of the present disclosure. The full wave rectifier with a center tapped transformer 160 circuit 150 includes a voltage source 140 between node A and node B, the center tapped transformer 160, diodes 104, 108 forming the full wave rectifier, and a filter capacitor 170. The center tapped transformer 160 includes a primary winding 162, a first secondary winding 164 provided between node C and node D, a second secondary winding 166 provided between node E and node F and a center tap 168 provided between node D and node E. The first secondary winding 164 and the second secondary winding 166 have the same number of turns. According to embodiments of the present disclosure, the number of turns for the first secondary winding 164 and the second secondary winding 166 is one (1) turn. The voltage source 140 supplies an alternating current (AC) input voltage Vin to the primary winding 162 of the center tapped transformer 160.

During the positive half-cycle of the input voltage Vin 140, diode 104 becomes forward biased (i.e., allows electric current) and diode 108 becomes reverse biased (i.e., blocks electric current). As illustrated in FIG. 1, the current flows through diode 104 as shown by current path represented with dashed line 101. Therefore, the first secondary winding 164 provides the output voltage for the center tapped transformer 160.

During the negative half-cycle of the input voltage Vin 140, diode 108 is forward biased and diode 104 is reverse biased. The current flows through diode 108 as shown by the current path represented by dashed and dotted line 102. Therefore, the second secondary winding 166 provides the output voltage for the center tapped transformer 160. In both cases, however, the current flow is unidirectional or a pulsating direct current (DC).

The center tap 168 is grounded and each of the diodes 104, 108 is connected to the remaining nodes of the first and second secondary windings 164, 166.

Because the output waveform of a full wave rectifier is not a standard or a pure DC voltage, filter capacitor 170 is provided in parallel to an output voltage to reduce ripples and increase the average output voltage.

According to an alternative embodiment of the present disclosure, power metal-oxide semiconductor field effect transistor (MOSFET)s may be used instead of diodes 104, 108.

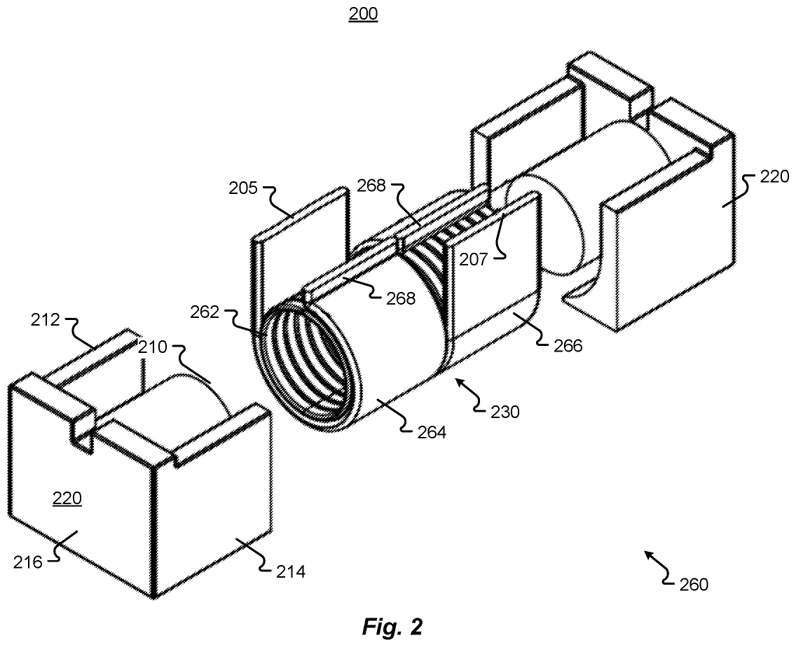

FIG. 2 depicts a perspective exploded view 200 of a conventional center tapped transformer 260. The conventional center tapped transformer 260 includes core members 220, primary winding 262, a first secondary winding 264 and a second secondary winding 266. Each of the core members 220 has an “E” shaped cross-section and includes side portions 212, 214, a center portion 210 and a top/bottom portion 216. The two core members 220 when combined, form a ferrite core with the center portions 210. The combined center portions 210 act as a winding core. Located on the outside of the winding core is a coil structure 230 including the primary winding 262, the first secondary winding 264 and the second secondary winding 266. The first secondary winding 264 is wound around one part of the primary winding 262 (approximately one half the length of the primary winding 262) and the second secondary winding 266 is wound around the other part of the primary winding 262 (approximately one half the length of the primary winding 262). One end of the first secondary winding 264 is connected to a center terminal 268 and the other end 205 of the first secondary winding 264 is provided for connection to a printed circuit board (PCB) which is not shown. One end of the second secondary winding 266 is connected to the center terminal 268 and the other end 207 of the second secondary winding 266 is provided for connection to a printed circuit board (PCB) which is not shown.

To form a magnetic field in the conventional center tapped transformer 260, the center portions 210 of the core members 220 having a high magnetic permeability are combined to form the winding core. The diameter or size of the winding core of the core members 220 is slightly smaller than the diameter or size of an opening provided by the coil structure 230 to form the conventional center tapped transformer 260.

For low output voltage, large load current conditions, the conventional center tapped transformer 260 having the coil structure 230 discussed above, is usually provided with each of the first and second secondary windings 264, 266 with one turn and one end of each of the first secondary winding 264 and the second secondary winding 266 is connected together. According to embodiments of the present disclosure, the turns ratio of the windings varies in different applications. For example, the turns ratio may be 17:1:1 with the primary winding 262 having 17 turns and each of the secondary windings 264, 266 having one turn. This turns ratio may be used when the primary voltage is 426 volts (V), the secondary output voltage is 12.5V and a half bridge two inductor and one capacitor (LLC) topology is used so the turns ratio is 426/12.5/2=17. Usually, the wire gauge for the primary and secondary windings is fine to get an approximate current density and utilize the core space as such as possible.

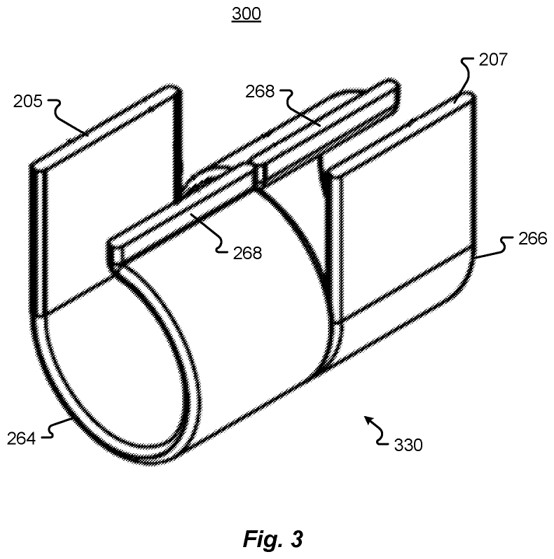

FIG. 3 depicts a perspective view 300 of a conventional coil structure 330. The coil structure 330 illustrated in FIG. 3 is similar to the coil structure 230 illustrated in FIG. 2 without the primary winding 262 being illustrated. As such, the coil structure 330 includes the first secondary winding 264 and the second secondary winding 266. As illustrated in FIG. 3, the first secondary winding 264 and the second secondary winding 266 of the coil structure 330 generally include a single thick copper sheet or several thin copper sheets arranged in parallel. With this type of coil structure 330 used in the full wave rectifier circuit discussed above, when the voltage of the primary winding 262 (illustrated in FIG. 2) is positive, the first secondary winding 264 is in operation and current flows through the first secondary winding 264. The second secondary winding 266, however, is not in operation and current does not flow through the second secondary winding 266. When the voltage of the primary winding 262 is negative, the secondary winding 266 is in operation and current flows through the secondary winding 266. The first secondary winding 264, however, is not in operation and current does not flow through the first secondary winding 264.

With this arrangement of the coil structure 330 as discussed above, only half of the primary winding 262 is covered by an operational secondary winding at any given point in time. With this conventional arrangement, the coupling between the primary winding 262 and the first and second secondary windings 264, 266 is ineffective and causes the overall efficiency of the conventional center tapped transformer 260 to suffer. Also, the ineffective coupling between the primary winding 262 and the first and second secondary windings 264, 266 causes large eddy current losses the primary coil 262 and each of the secondary coils 264, 266. In addition, the current balance is not optimal in the first and second secondary windings 262, 266 for the conventional center tapped transformer 260 which uses a parallel structure in the first and second secondary windings 264, 266. This current imbalance issue also affects the loss in the windings. Moreover, the use of a single thick copper sheet or the use of several thin copper sheets in parallel only reduces the DC resistance of the first and second secondary windings 264, 266, but provides very limited reduction in AC resistance. Thus, the AC losses for the copper sheet(s) are still very large. Therefore, the conventional center tapped transformer 260 experiences very large coil losses which hampers the efficiency of the conventional center tapped transformer 260.

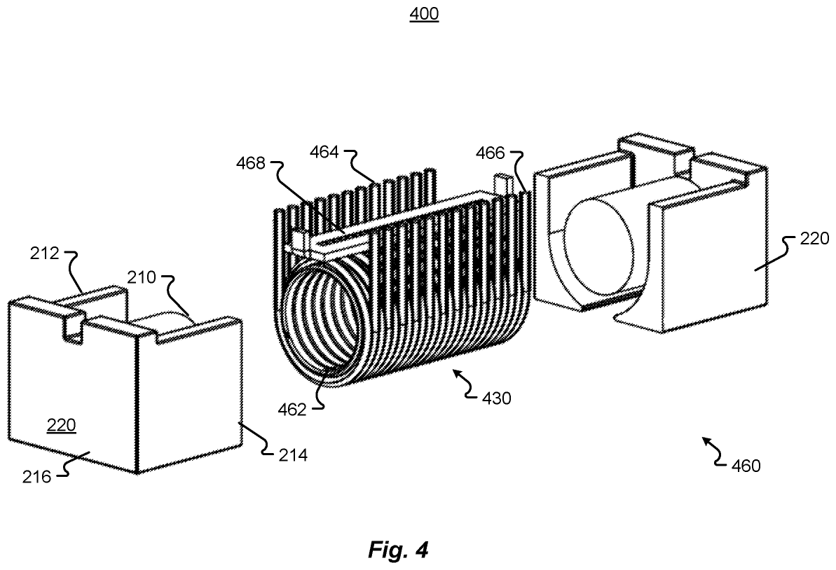

FIG. 4 depicts a first perspective exploded view 400 of a center tapped transformer 460 according to embodiments of the present disclosure. The first perspective exploded view 400 of the center tapped transformer 460 according to embodiments of the present disclosure, is illustrated in an upside-down configuration for ease of explanation. The center tapped transformer 460 according to embodiments of the present disclosure at least includes core members 220, primary winding 462, a first secondary winding 464 and a second secondary winding 466. Each of the core members 220 has an “E” shaped cross-section and includes side portions 212, 214, a center portion 210 and a top/bottom portion 216. The two core members 220 when combined, form a ferrite core with the center portions 210. The combined center portions 210 act as a winding core. Located on the outside of the winding core is a coil structure 430 including the primary winding 262, the first secondary winding 464 and the second secondary winding 466.

The first secondary winding 464 is interleaved with the second secondary winding 466 to form an interleaved aligned first and second secondary winding coil structure. As discussed in greater detail below, interleaving the first and second secondary windings 464, 466 means alternating one member of the first secondary winding 464 with a corresponding member of the second secondary winding 466. Moreover, one end of each member of the interleaved aligned first secondary winding 464 is connected to a busbar 468 and the other end of each member of the interleaved aligned first secondary winding 464 is provided for coupling to a PCB. Likewise, one end of each member of the interleaved aligned second secondary winding 466 is connected to the busbar 468 and the other end of each member of the interleaved aligned second secondary winding 466 is provided for coupling to a PCB. With this interleaved alignment an entire surface of the primary winding 462 is covered by each of the first and second secondary windings 464, 466. According to an embodiment of the present disclosure, the busbar 468 may be made of a metal such as copper.

To form a magnetic field in the center tapped transformer 460, the center portions 210 of the core members 220 having a high magnetic permeability are combined to form the winding core. The diameter or size of the winding core of the core members 220 is slightly smaller than the diameter or size of an opening provided by the coil structure 430 to form the center tapped transformer 460.

As the secondary winding current of each of the first secondary winding 464 and the second secondary winding 466 is very large and has a large AC component, according to embodiments of the present disclosure, Litz wire is used for each of the primary wiring 462, the first secondary wiring 464 and the second secondary wiring 466 in order to reduce the coil loss. Litz wire, which is a wire that includes a plurality of individual strands of conductive material that are braided, stranded, or woven together into a bundled cable-like structure, may be used for the various windings of an electrical transformer. Moreover, Litz wire is typically made of twisted bundles of individually insulated fine copper wires or manufactured in a woven form of a uniform pattern. The Litz wire has a high impedance per unit area and is widely used to reduce cable impedance or reduce cable thickness at high frequencies.

Thus, the Litz wire can be used to minimize power loss and reduce skin-effect and proximity effect at high frequency operations. Multiple wire bundles can suppress the increase in AC resistance than a single coarse wire with the same cross section. It is possible to prevent the temperature rise of the windings, thereby enabling high efficiency, miniaturization, and high speed of electric devices including transformers.

The Litz wire constituting the primary winding 462, the first secondary winding 464 and the second secondary winding 466 is a copper wire with enamel for insulation to the copper wire. A predetermined thickness is coated with epoxy for bonding between the copper wire on the enamel sequentially. A copper wire of about 0.12 mm may be formed by twisting 1000 to 2000 strands but is not limited thereto. In addition, the production of the primary winding 462, the first secondary winding 464 and the second secondary winding 466 using the Litz wire simplifies the process of the transformer, since the flow of current is desired, there is little heat generation due to energy loss.

According to one embodiment of the present disclosure, the diameter and number of strands of Litz wire used in parallel can be adjusted according to the current load of an electronic transforming device. For example, and according to one embodiment of the present disclosure, a 14*φ0.1 mm*140P Litz wire for each of the first secondary winding 464 and the second secondary winding 466 with a current load of about 180 amp (A). This means that there are 14 strands of wire, and each strand of wire has 140 φ0.1 mm wires in parallel.

With the first and second secondary windings 464, 466 each covering the entire surface of the primary winding 462 in an interleaved alignment, when either the first secondary winding 464 or the second secondary winding 466 is in operation, the first and second secondary windings 464, 466 are always coupled closely with the primary winding 462. The close coupling of the first and second secondary windings 464, 466 along the entire surface of the primary winding 462, improves the efficiency of the center tapped transformer 460. Moreover, the close coupling of the first and second secondary windings 464, 466 along the entire surface of the primary winding 462 reduces the eddy current losses in the coils and improves the current balance of parallel windings. This arrangement of a close coupling of the first and second secondary windings 464, 466 along the entire surface of the primary winding 462 reduces MOSFET voltage stress for both the primary and secondary and also improves the efficiency of the center tapped transformer 460. That is, the voltage stress is caused by leakage inductance. The better the coupling of the first and second secondary windings 464, 466 provides a very low leakage inductance and therefore, a small voltage stress is created. Moreover, the use of Litz wire for each of the primary winding 462, the first secondary winding 464 and the second secondary winding 466 significantly reduces AC winding loss and greatly improves the efficiency of the center tapped transformer 460.

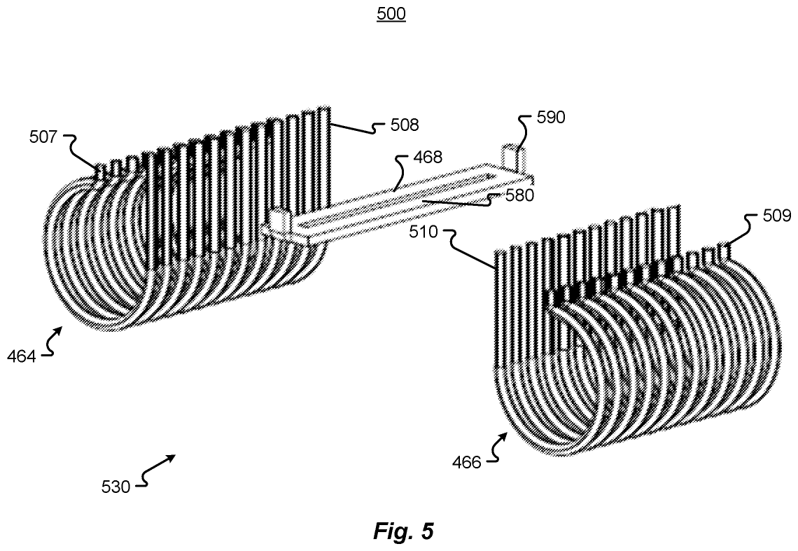

FIG. 5 depicts a perspective view 500 of an unassembled coil structure 530 of the secondary windings 464, 466 illustrated in FIG. 4 according to embodiments of the present disclosure. The perspective view 500 is illustrated in an upside-down configuration for ease of explanation. As illustrated in FIG. 5, each member of the first secondary winding 464 includes a center terminal 507 and a connection leg 508. Likewise, each member of the second secondary winding 466 includes a center terminal 509 and a connection leg 510. Each of the center terminals 507, 509 is provided within a slot 580 of the busbar 468. Busbar 468 also includes terminals 590 for coupling to a PCB. Moreover, each of the connection legs 508, 510 is provided for coupling to the PCB. According to an alternative embodiment of the present disclosure, the busbar 468 may be made from other types of metal such as aluminum or another type of metal. Having the center terminals 507, 509 of each member of the interleaved aligned first and second secondary windings coil structure connected to the busbar 468 allows for the busbar 468 with the center terminals 507, 509 provided thereon, to be easily connected and disconnected from the PCB.

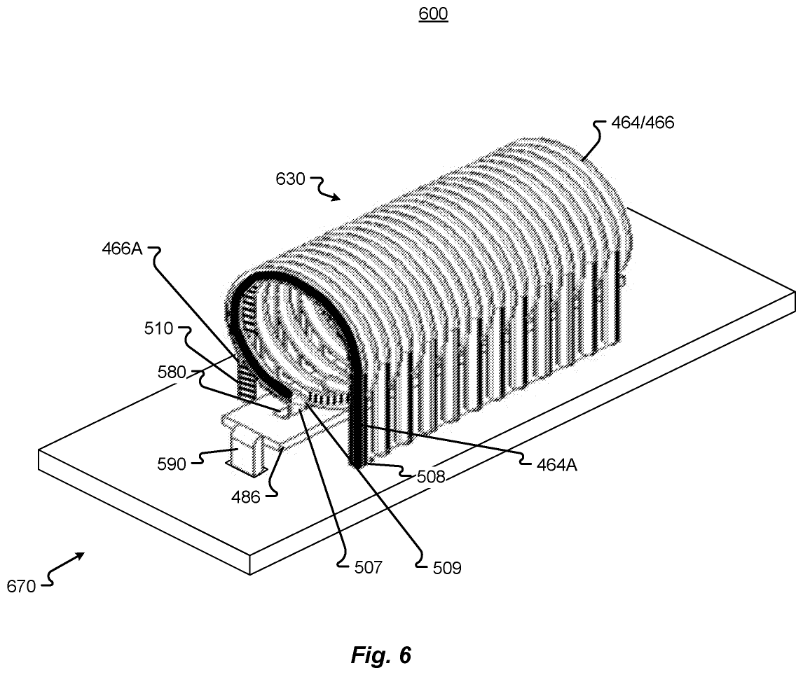

FIG. 6 depicts a perspective view 600 of an assembled coil structure 630 of the secondary windings 464, 466 illustrated in FIG. 4 according to embodiments of the present disclosure. As illustrated in FIG. 6, the coil structure 630 is mounted onto a PCB 670. A first member 464A of the first secondary winding 464 (illustrated with dark shading) is interleaved with a first member 466A of the second secondary winding 466 (illustrated with striped shading). The center terminal 507 of the first member 464A of the first secondary winding 464 is provided within the slot 580 of the busbar 468 and the connection leg 508 of the first member 464A of the first secondary winding 464 is coupled to the PCB 670. The center terminal 509 of the first member 466A of the second secondary winding 466 is also provided within the slot 580 of the busbar 468, next to the center terminal 507 of the first member 464A of the first secondary winding 464. The connection leg 510 of the first member 466A of the second secondary winding 466 is also connected to the PCB 670. Each of the remaining members of each of the first and second secondary windings 464, 466 is arranged in the same interleaved alignment as the first and second members 464A, 466A of the first and second secondary windings 464, 466.

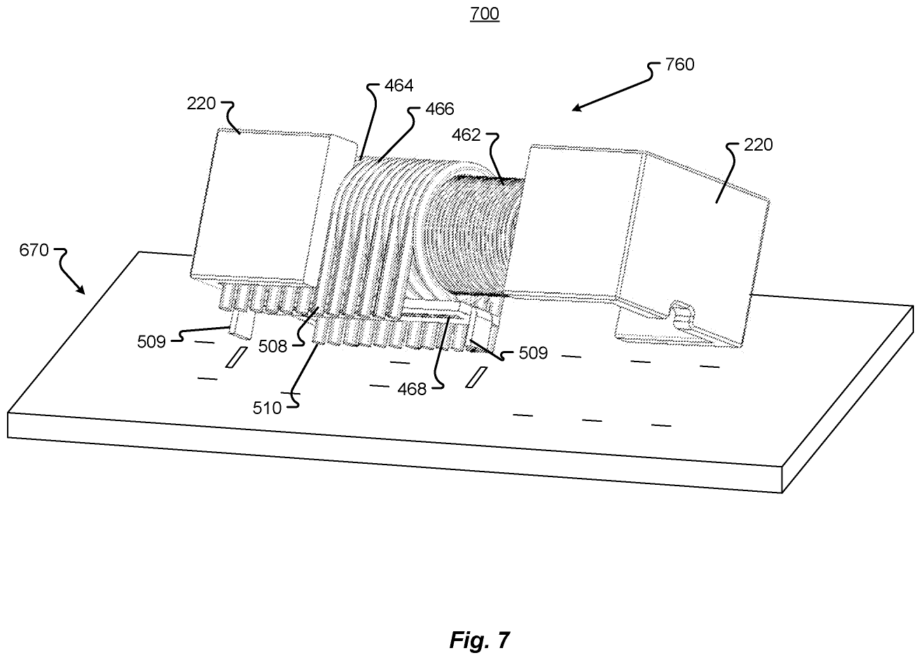

FIG. 7 depicts a second perspective exploded view 700 of a center tapped transformer 760 according to embodiments of the present disclosure. The center tapped transformer 760 according to embodiments of the present disclosure at least includes core members 220, primary winding 462, first secondary winding 464 and second secondary winding 466. The first secondary winding 464 is interleaved with the second secondary winding 466 and provided over the primary winding 462. The center tapped transformer 760 is provided above PCB 670 such that terminals 590 of the busbar 468 are coupled to the PCB 670. Also, connection legs 508, 510 of each of the members of the first and second secondary windings 464, 466 are provided to be coupled to the PCB 670.

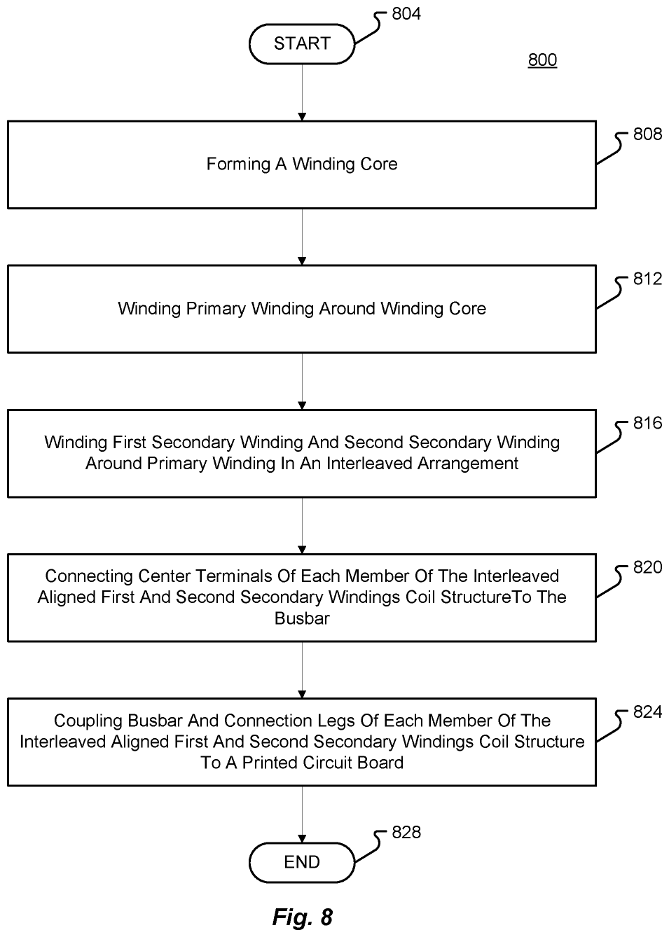

FIG. 8 illustrates a method 800 for forming a center tapped transformer 460 with reduced coil loss and enhanced coupling between the primary winding 462 and the first and second secondary windings 464, 466 according to embodiments of the present disclosure. For example, the method 800 may be used for forming and assembling the center tapped transformer 460 as described with reference to FIG. 4 that at least includes the coil structure 430 as described herein and with reference to FIG. 4. While a general order for the steps of the method 800 is shown in FIG. 8, the method 800 can include more or fewer steps or can arrange the order of the steps differently than those shown in FIG. 8. Generally, the method 800 starts with a START operation at step 804 and ends with an END operation at step 828. The method 800 can be executed as a set of computer-executable instructions executed by an assembly machine (e.g., robotic assembly system, automation assembly system, computer aided drafting (CAD) machine, etc.) and encoded or stored on a computer readable medium. Hereinafter, the method 800 shall be explained with reference to the components, devices, assemblies, environments, etc. described in conjunction with FIGS. 1-7.

The method 800 may begin with the START operation at step 804 and proceeds to step 808 where a winding core is formed. According to embodiments of the present disclosure, the winding core is formed by combining each of the core members 220 together. A ferrite core is formed by the center portions 210 being joined. The joined center portions 210 act as a winding core. After forming the winding core at step 808, method 800 proceeds to step 812, where the primary winding 462 constructed of Litz wire is wound around the winding core. According to embodiments of the present disclosure, the primary winding 462 is wrapped around the winding core as many times as necessary to achieve the desired number of turns. After the primary winding 462 has been wound around the winding core at step 812, method 800 proceeds to step 816, where the first secondary winding 464 and the second secondary winding 466 are wound around the primary winding 462 in an interleaved alignment. According to embodiments of the present disclosure, the first and second secondary windings 464, 466 each includes one turn and are also made of Litz wire. The first and second secondary windings 464, 466 are wound around the primary winding 462 in an alternate manner with a first member 464A of the first secondary winding 464 followed by a first member 466A of the second secondary winding 466, followed by a second member of the first secondary winding 464A and so on, as discussed in greater detail above with reference to FIG. 6. The arrangement of the first and second secondary windings form an interleaved aligned first and second secondary windings coil structure.

After the interleaved aligned first and second secondary windings coil structure has been wound around the primary winding 462 at step 816, method 800 proceeds to step 820 where center terminals of each of the members of the interleaved aligned first and second secondary windings coil structure are connected to the busbar 468. After the center terminals of each of the members of the interleaved aligned first and second secondary windings coil structure are connected to the busbar 468 at step 820, method 800 proceeds to step 824, where the busbar 468 and the connection legs 508, 510 of each member of the interleaved aligned first and second secondary windings coil structure are coupled to the PCB 670. Method 800 ends with the END operation at step 828.

The features of the various embodiments described herein are not intended to be mutually exclusive. Instead, features and aspects of one embodiment may be combined with features or aspects of another embodiment. Additionally, the description of a particular element with respect to one embodiment may apply to the use of that particular element in another embodiment, regardless of whether the description is repeated in connection with the use of the particular element in the other embodiment.

Examples provided herein are intended to be illustrative and non-limiting. Thus, any example or set of examples provided to illustrate one or more aspects of the present disclosure should not be considered to comprise the entire set of possible embodiments of the aspect in question. Examples may be identified by the use of such language as “for example,” “such as,” “by way of example,” “e.g.,” and other language commonly understood to indicate that what follows is an example.

The phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more,” and “at least one” can be used interchangeably herein. It is also to be noted that the terms “comprising,” “including,” and “having” can be used interchangeably.

The systems of this disclosure have been described in relation to the coupling of an interleaved aligned first and second secondary windings coil structure with a primary winding of a center tapped transformer. However, to avoid unnecessarily obscuring the present disclosure, the preceding description omits a number of known structures and devices. This omission is not to be construed as a limitation of the scope of the claimed disclosure. Specific details are set forth to provide an understanding of the present disclosure. It should, however, be appreciated that the present disclosure may be practiced in a variety of ways beyond the specific detail set forth herein.

A number of variations and modifications of the disclosure can be used. It would be possible to provide for some features of the disclosure without providing others.

The present disclosure, in various embodiments, configurations, and aspects, includes components, methods, processes, systems and/or apparatus substantially as depicted and described herein, including various embodiments, subcombinations, and subsets thereof. Those of skill in the art will understand how to make and use the systems and methods disclosed herein after understanding the present disclosure. The present disclosure, in various embodiments, configurations, and aspects, includes providing devices and processes in the absence of items not depicted and/or described herein or in various embodiments, configurations, or aspects hereof, including in the absence of such items as may have been used in previous devices or processes, e.g., for improving performance, achieving ease, and/or reducing cost of implementation.

The foregoing discussion of the disclosure has been presented for purposes of illustration and description. The foregoing is not intended to limit the disclosure to the form or forms disclosed herein. In the foregoing Detailed Description for example, various features of the disclosure are grouped together in one or more embodiments, configurations, or aspects for the purpose of streamlining the disclosure. The features of the embodiments, configurations, or aspects of the disclosure may be combined in alternate embodiments, configurations, or aspects other than those discussed above. This method of disclosure is not to be interpreted as reflecting an intention that the claimed disclosure requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description.

Any one or more of the aspects/embodiments as substantially disclosed herein.

Any one or more of the aspects/embodiments as substantially disclosed herein optionally in combination with any one or more other aspects/embodiments as substantially disclosed herein.

One or means adapted to perform any one or more of the above aspects/embodiments as substantially disclosed herein.

What is claimed is:

1. A method for forming a center tapped transformer, comprising:
forming a winding core;
winding a primary winding around the winding core; and
winding a first secondary winding and a second secondary winding in an interleaved alignment around the primary winding.

2. The method for forming a center tapped transformer according to claim 1, further comprising alternating members of the first secondary winding with corresponding members of the second secondary winding to form an interleaved aligned first and second secondary windings coil structure.

3. The method for forming a center tapped transformer according to claim 2, further comprising:
connecting center terminals for each member of the interleaved aligned first and second secondary windings coil structure to a busbar; and
coupling the busbar to a printed circuit board.

4. The method for forming a center tapped transformer according to claim 3, further comprising coupling connection legs for each member of the interleaved aligned first and second secondary windings coil structure to the printed circuit board.

5. The method for forming a center tapped transformer according to claim 1, further comprising forming each of the first secondary winding and the second secondary winding from Litz wire.

6. The method for forming a center tapped transformer according to claim 1, wherein each of the first and second secondary windings includes one turn.

7. The method for forming a center tapped transformer according to claim 1, further comprising combining core members together to form the winding core.

8. The method for forming a center tapped transformer according to claim 7, wherein each of the core members includes an E-shaped section.

9. The method for forming a center tapped transformer according to claim 1, further comprising applying the center tapped transformer in a full wave rectifier circuit.

10. The method for forming a center tapped transformer according to claim 1, further comprising forming the primary winding from Litz wire.

11. A center tapped transformer, comprising:
a winding core;
a primary winding wound around the winding core; and
a first secondary winding and a second secondary winding wound in an interleaved alignment around the primary winding.

12. The center tapped transformer according to claim 11, wherein members of the first secondary winding are alternated with corresponding members of the second secondary winding to form an interleaved aligned first and second secondary windings coil structure.

13. The center tapped transformer according to claim 12, further comprising a busbar,
wherein center terminals for each member of the interleaved aligned first and second secondary windings coil structure is connected to the busbar, and
wherein the busbar is coupled to a printed circuit board.

14. The center tapped transformer according to claim 13, wherein connection legs for each member of the interleaved aligned first and second secondary windings coil structure is coupled to the printed circuit board.

15. The center tapped transformer according to claim 11, wherein each of the first secondary winding and the second secondary winding is formed from Litz wire.

16. The center tapped transformer according to claim 11, wherein each of the first and second secondary windings includes one turn.

17. The center tapped transformer according to claim 11, wherein core members are combined together to form the winding core.

18. The center tapped transformer according to claim 17, wherein each of the core members includes an E-shaped section.

19. The method for forming a center tapped transformer according to claim 1, wherein the center tapped transformer is applied in a full wave rectifier circuit.

20. A circuit module, comprising:
a circuit board having at least one mounting area; and
a center tapped transformer coupled to the at least one mounting area,
wherein the center tapped transformer comprises:
a winding core;
a primary winding wound around the winding core; and
a first secondary winding and a second secondary winding wound in an interleaved alignment around the primary winding.
